(19) United States
(12) Patent Application Publication
(10) Pub. No.: US 2009/0050208 A1
(43) Pub. Date: Feb. 26, 2009

(54) METHOD AND STRUCTURES FOR CONTROLLING THE GROUP IIIA MATERIAL PROFILE THROUGH A GROUP IBIIIAVIA COMPOUND LAYER

(76) Inventors: Bulent M. Basol, Manhattan Beach, CA (US); Yuriy B. Matus, Pleasanton, CA (US)

Correspondence Address: PILLSBURY WINTHROP SHAW PITTMAN LLP, P.O. BOX 10500, MCLEAN, VA, 22102, US

(21) Appl. No.: 12/191,220

(22) Filed: Aug. 13, 2008

Related U.S. Application Data
(63) Continuation-in-part of application No. 11/740,248, filed on Apr. 25, 2007.
(60) Provisional application No. 60/865,385, filed on Nov. 10, 2006.
(60) Provisional application No. 60/862,164, filed on Oct. 19, 2006.

(51) Int. Cl. H01L 31/0272; H01L 21/20; H01L 29/22

(52) U.S. Cl. 136/264; 438/509; 257/614; 257/E29.094; 257/E21.09; 257/E31.008

(57) ABSTRACT

A method is provided for forming a Group IBIIIAVIA solar cell absorber layer including indium (In) and gallium (Ga) that are distributed substantially uniformly between the top surface and the bottom surface of the absorber layer. In one embodiment method includes forming a precursor by depositing a metallic layer including copper (Cu), indium (In) and gallium (Ga) on the base, and depositing a film comprising selenium (Se) and tellurium (Te) on the metallic layer. In the precursor, the molar ratio of Te to Ga is equal to or less than 1. In the following step, the precursor is heated to a temperature range of 400-600° C. to form the Group IBIIIAVIA solar cell absorber layer.

### CLAIM OF PRIORITY

This application is a Continuation-in-Part (CIP) of U.S. patent application Ser. No. 11/740,248, filed Apr. 25, 2007, entitled “Method and Apparatus for Controlling Composition Profile of Copper Indium Gallium Chalcogenide Layers” expressly incorporated herein by reference.

### FIELD OF THE INVENTIONS

The present inventions relate to method and apparatus for preparing thin films of semiconductor films for radiation detector and photovoltaic applications, specifically to a method and apparatus for processing Group IBIIIAVIA compound layers for thin film solar cells.

### BACKGROUND

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB such as (Cu), silver (Ag), gold (Au), Group IIIA such as boron (B), aluminum (Al), gallium (Ga), indium (In), and thallium (Tl), and Group VIA such as oxygen (O), sulfur (S), selenium (Se), tellurium (Te), and polonium (Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications. Among these compounds, Cu (In,Ga) (S,Se)₂ is the most advanced and solar cells in the 12-20% efficiency range have been demonstrated using this material as the absorber. Aluminum (Al) containing chalcopyrites such as Cu(In,Al)Se₂ layers have also yielded over 12% efficient solar cells. Although from the optical bandgap value consideration point of view, the Group IBIIIAVIA compound layers containing Te are of interest for photovoltaic applications, there has not been a report to this date on high efficiency solar cells made on such telluride films. However, limited amount of studies have been carried out on CuInTe₂ which has an optical bandgap of about 1 eV (see for example, Assali et al., Solar Energy Materials and Solar Cells, 59 (1999) 349, Roy et al., Vacuum, 65 (2002) 27, Ishizaki et al., Surface Coating Technology, 182 (2004) 156, and, Orts et al., Solar Energy Materials and Solar Cells, 91 (2007) 621), and copper gallium telluride (CuGaTe₂) which has an optical bandgap of above 1.2 eV (see for example, Reddy et al., Thin Solid Films, 292 (1997) 14).

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which includes a material in the family of Cu(In,Ga,Al)(S,Se,Te)₂ , is grown over a conductive layer 13 or contact layer, which is previously deposited on the substrate 11 and which acts as the electrical contact to the device. The substrate 11 and the conductive layer 13 form a base 13A on which the absorber film 12 is formed. Various conductive layers comprising molybdenum (Mo), tantalum (Ta), tungsten (W), titanium (Ti), stainless steel and the like have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a cadmium sulfide (CdS), zinc oxide (ZnO) or CdS/ZnO etc. stack is formed on the absorber film. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1.

In a thin film solar cell employing a Group IBIIIAVIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In+Ga). Furthermore, some of the important parameters of the cell, such as its open circuit voltage, short circuit current and fill factor vary with the molar ratio of the IIIA elements, i.e. the Ga/(Ga+In) molar ratio. In general, for good device performance Cu/(In+Ga) molar ratio is kept at around or below 1.0. As the Ga/(Ga+In) molar ratio increases, on the other hand, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA components in the composition. It should be noted that although the chemical formula is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

If there is more than one Group VIA material or element in the compound, the electronic and optical properties of the Group IBIIIAVIA compound are also a function of the relative amounts of the Group VIA elements. For Cu(In,Ga)(S,Se)₂, for example, compound properties, such as resistivity, optical bandgap, minority carrier lifetime, mobility etc., depend on the Se/(S+Se) ratio as well as the previously mentioned Cu/(In+Ga) and Ga/(Ga+In) molar ratios. Consequently, solar-to-electricity conversion efficiency of a CIGS(S)-based solar cell depends on the distribution profiles of Cu, In, Ga, Se and S through the thickness of the CIGS(S) absorber. For example, curve A in FIG. 2 schematically shows a typical distribution profile for the Ga/(Ga+In) molar ratio for a Cu(In,Ga)Se₂ absorber layer formed by a two-stage process involving selenization of metallic precursors comprising Cu, In and Ga. Examples of such two-stage processes may be found in various publications. For example, U.S. Pat. No. 6,048,442 discloses a method comprising sputter-depositing a stacked precursor film containing a Cu—Ga alloy layer and an In layer to form a Cu—Ga/In stack on a metallic back electrode layer in the first stage of the process, and then reacting this precursor stack film with one of Se and S to form the absorber layer during the second stage of the process. U.S. Pat. No. 6,092,669 describes the sputtering-based equipment for producing such absorber layers.

Referring back to curve A in FIG. 2, one problem faced with the selenization type processes (also called two-stage processes) is the difficulty to distribute Ga uniformly through the thickness of the absorber layer formed after reaction of the metallic precursor film with Se. It is believed that when a metallic precursor film comprising Cu, In and Ga is deposited first on a base and then reacted with Se, the Ga-rich phases segregate to the film/base interface (or the film/contact interface) because reactions between Ga-bearing species and Se are slower than the reactions between In-bearing species and Se. Therefore, such a process yields compound absorber layers with surfaces that are rich in In and poor in Ga. When a solar cell is fabricated on such an absorber layer, the active junction of the device is formed within the surface region with a low Ga/(Ga+In) ratio as shown by Curve A in FIG. 2. This surface portion is practically a CuInSe₂ layer with a small bandgap and consequently solar cells fabricated on such layers display low open circuit voltages (typically 400-500 mV) and thus lower efficiencies. In contrast, curve B in FIG. 2 schematically shows a relatively uniform Ga/(Ga+In) molar ratio distribution. Solar cells fabricated on such absorbers display higher voltage values of typically over 600 mV due to the presence of Ga (typically 20-30%) near the surface region. The world record efficiency of 19.5% was demonstrated on such an absorber obtained by a co-evaporation process. Obtaining similar Ga distribution profiles for absorbers fabricated using two-stage processes is important to increase the performance of such absorbers.

### SUMMARY

The present inventions provide methods and precursor structures to form a Group IBIIIAVIA solar cell absorber layer.

In one embodiment there is provided a method of forming a Group IBIIIAVIA compound layer on a base comprising: forming a precursor layer on the base, the precursor layer comprising at least one Group IB material, indium (In), tellurium (Te) and at least one of gallium (Ga) and aluminum (Al), wherein the step of forming the precursor layer comprises growing a first layer on the base, the first layer comprising at least one of the indium (In), gallium (Ga), aluminum (Al) and a Group IB material and excluding tellurium (Te), and depositing a second layer comprising tellurium (Te) on the first layer; reacting the precursor layer with selenium (Se); and forming the Group IBIIIAVIA compound layer on the base.

In another embodiment there is provided a method of forming a Group IBIIIAVIA compound layer on a base comprising: forming a precursor layer on the base by way of depositing a precursor material by initiating the deposition at a beginning deposition stage and ending the deposition at a final deposition stage, wherein the precursor material comprises at least one Group IB material, indium (In) as a Group IIIA material, at least one other Group IIIA material and tellurium (Te), and wherein the tellurium (Te) is deposited during at least one of the final deposition stage and an intermediate deposition stage that takes place between the beginning deposition stage and the final deposition stage; providing selenium (Se); reacting the precursor layer with selenium (Se); and forming the Group IBIIIAVIA compound layer on the base.

In a further embodiment there is provided a method of forming on a surface of a base, a Cu(In,Ga)(Se,Te)₂ compound layer with a top surface and a bottom surface, wherein the bottom surface is adjacent to the surface of the base and wherein indium (In) and gallium (Ga) are distributed substantially uniformly between the top surface and the bottom surface, the method comprising; depositing a metallic layer on the surface of the base, wherein the metallic layer comprises copper (Cu), indium (In) and gallium (Ga), and wherein the thickness of the metallic layer is at least 200 nm; disposing a film comprising selenium (Se) and tellurium (Te) over the metallic layer thus forming a structure; and heating the structure to a temperature range of 400-600° C.

In another embodiment there is provided a precursor structure for forming a Group IBIIIAVIA solar cell absorber on a surface of a base, comprising: a metallic layer formed on the surface of the base, the metallic layer comprising at least one Group IB material, indium (In) as a Group IIIA material and at least one another Group IIIA material, wherein the thickness of the metallic layer is at least 200 nm; and a Group VIA layer comprising tellurium (Te) and selenium (Se) formed on the metallic layer.

In another embodiment there is provided a solar cell absorber layer, having a top surface and a bottom surface, formed on a base, wherein the bottom surface is adjacent to the base, comprising: copper (Cu), gallium (Ga), indium (In), selenium (Se), and tellurium (Te); and wherein indium (In) and gallium (Ga) are distributed substantially uniformly between the top surface and the bottom surface of the solar cell absorber layer, and the molar ratio of Te to Ga is less than 1.

These above embodiments, as well as other aspects and advantages of the present inventions, will be described further herein.

### BRIEF DESCRIPTION OF THE DRAWINGS

FIG. 1 is a cross-sectional view of a solar cell employing a Group IBIIIAVIA absorber layer.

FIG. 2 shows Ga/(Ga+In) molar ratios in two different CIGS absorber layers, one with a Ga-poor surface (curve A) and the other with a more uniform Ga distribution (curve B).

FIG. 3 shows a set of process steps in accordance with one embodiment.

FIG. 4 shows another set of process steps in accordance with another embodiment.

FIG. 5 is a cross sectional schematic showing a precursor film formed on a base according to one embodiment.

FIG. 6 is a cross sectional schematic showing a precursor film formed on a base according to another embodiment.

FIG. 6A shows a Group IBIIIAVIA compound layer formed on the base using the precursor film of FIG. 6.

FIG. 6B shows a concentration depth profile of the ingredients in the compound layer of FIG. 6A.

FIG. 7 shows another precursor film comprising a layer of Te.

FIG. 7A shows a Group IBIIIAVIA compound layer formed on the base using the precursor film of FIG. 7.

FIG. 7B shows a concentration depth profile of the ingredients in the compound layer of FIG. 7A.

FIG. 8 shows two different quantum efficiency data collected from two different solar cells.

FIG. 9 shows a schematic drawing of Se—Te binary phase diagram.

FIG. 10 shows three different Ga profiles for three different Group IBIIIAVIA compound layers prepared under three different conditions.

FIGS. 11A-11D show alternative precursor structures.

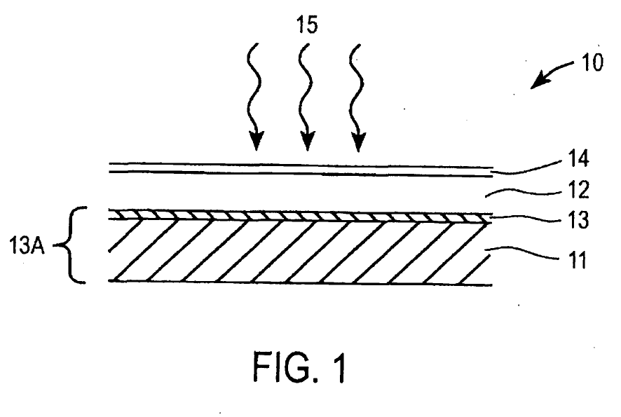

### DETAILED DESCRIPTION

FIG. 3 shows the process steps for growing a Cu(In,Ga)Se₂ absorber layer on a base, wherein the Ga distribution within the absorber layer is substantially uniform. As can be seen from FIG. 3, the first step of the process (Step I) is deposition of a precursor film on a base, the precursor film comprising Cu, In and Ga. As an example, the amounts of Cu, In and Ga may be such that Cu/(In+Ga) molar ratio in the film may be in the range of 0.7-1.0, preferably in the range of 0.8-0.9, and the Ga/(Ga+In) molar ratio may be in the range of 0.1-0.5, preferably in the range of 0.2-0.35. The precursor film may be deposited on the base by a variety of techniques such as electrodeposition, evaporation, sputtering, ink deposition etc. The precursor film may comprise nano particles made of Cu and/or In and/or Ga and/or their mixtures and/or alloys. Alternately, the precursor film may comprise at least two sub-layers, each sub-layer comprising at least one of Cu, In and Ga. Precursor film examples include but are not limited to Cu/In/Ga, Cu/Ga/In, Cu—Ga/In, Cu—In/Ga, Cu/Ga/Cu/In stacks, etc., where Cu—In and Cu—Ga refers to mixtures or alloys of Cu and In and Cu and Ga, respectively.

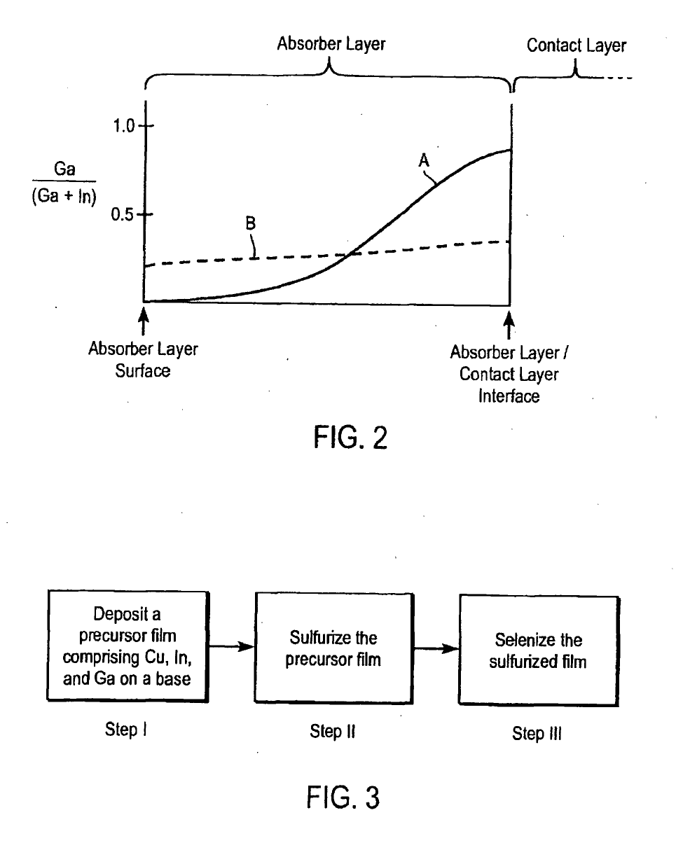

Referring back to FIG. 3, the second step (Step II) of the process involves a reaction step wherein the precursor film is reacted with S species. Such sulfurization or sulfidation reaction may be achieved in various ways. Typically, the reaction step may involve heating the precursor film to a temperature range of 200-600° C. in the presence of S provided by sources such as solid or liquid S, H₂S gas, S vapors, etc., for periods ranging from 1 minute to 1 hour. The S vapor may be generated by heating solid or liquid sources of S or by organometallic S sources, among others. During the reaction with S, Ga species (such as Cu—Ga intermetallics, Ga—S species, Ga—In—S species, Cu—Ga—S species, Cu—In—Ga—S species, etc.) get distributed relatively uniformly (as shown in curve B of FIG. 2) through the reacting precursor layer. This is because reaction of Ga species with S is fast, unlike the reaction of Ga species with Se, which, as described before, is slow. As a result of the Step II of the process a reacted film or a sulfurized film is formed on the base, the reacted film comprising Cu, In, Ga, and S, wherein the Ga is distributed substantially uniformly through the thickness of the reacted film. It should be noted that the sulfurization of the precursor film may be a complete reaction or an incomplete reaction during this Step II of the process. If the reaction is complete, then ternary or quaternary compounds such as Cu(In,Ga)S₂ phases would be formed. If the reaction is incomplete, then binary and/or ternary, and/or quaternary phases such as Ga—S, In—S, Ga—In—S, Cu—S, Cu—Ga—S, etc. may form in place of or in addition to the Cu(In,Ga)S₂ phases. The important point, however, is the fact that irrespective of the phase content, the Ga distribution in the reacted film is substantially uniform. It should be noted that the precursor film may comprise Se in addition to Cu, In, and Ga. In this case the amount of Se in the precursor layer is preferably less than 80% of the amount needed to form a Cu(In,Ga)Se₂ layer. In other words, the Se/Cu molar ratio in the precursor film is less than or equal to 1.6, more preferably less than 1.0. By limiting the amount of Se in the precursor film, it is assured that reaction of Ga and Se species are not complete and that the Ga and S species can react during the Step II of the process and Ga distribution through the film may be achieved.

The last step (Step III) of the process in FIG. 3 is substantial replacement of S in the sulfurized or reacted film with Se. To achieve this, the reacted film of Step II is exposed to Se species at elevated temperatures (selenization), preferably in the range of 250-600 C, more preferably in the range of 400-575 C, for a period of time which may be in the range of 1 minute to 1 hour, preferably in the range of 5 minutes to 30 minutes. As a result of this selenization step (Step III), the sulfurized film is converted into a Cu(In,Ga)Se₂ absorber layer while the substantially uniform distribution of Ga within the film is preserved yielding a distribution similar to that shown in curve B of FIG. 2. It should be noted that by adjusting the times and temperatures employed during Step III of the process, certain degree of S may be left in the absorber layer. The S/(Se+S) ratio in the final absorber layer may be less than 0.3, preferably less than 0.2, most preferably less than 0.1. Higher selenization temperatures and/or longer selenization times would replace more of the S within the reacted film with Se, thus yielding smaller S/(Se+S) ratio in the final absorber. The Step III utilizes an observation that Se has the capability to replace S when an S containing binary, ternary or quaternary material comprising at least one of Cu, In and Ga is exposed to Se at elevated temperature.

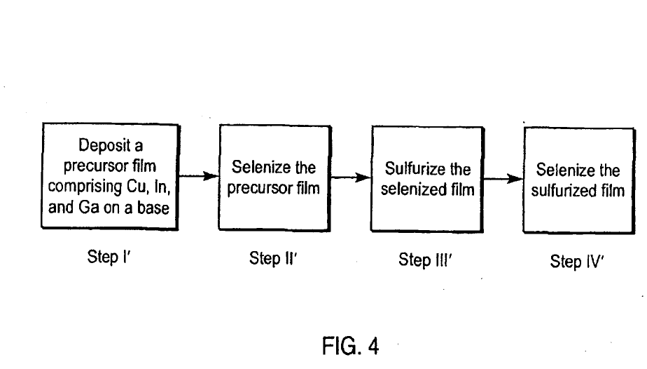

FIG. 4 shows the process steps of another embodiment that yields CIGS layers with substantially uniform Ga distribution. As can be seen from FIG. 4, the first step (Step I) of the process is deposition of a precursor film on a base, the precursor film comprising Cu, In and Ga. As an example, the amounts of Cu, In and Ga may be such that Cu/(In+Ga) molar ratio in the film may be in the range of 0.7-1.0, preferably in the range of 0.8-0.9, and the Ga/(Ga+In) molar ratio may be in the range of 0.1-0.5, preferably in the range of 0.2-0.35. The precursor film may be deposited on the base by a variety of techniques such as electrodeposition, evaporation, sputtering, ink deposition etc. The precursor film may comprise nano particles made of Cu and/or In and/or Ga and/or their mixtures and/or alloys. Alternately, the precursor film may comprise at least two sub-layers, each sub-layer comprising at least one of Cu, In and Ga.

Referring back to FIG. 4, the second step (Step II) of the process involves a reaction step wherein the precursor film is reacted with Se species (selenization). Such reaction or selenization may be achieved in various ways. Typically, the reaction step may involve heating the precursor film to a temperature range of 200-500° C. in the presence of Se provided by sources such as solid or liquid Se, H₂Se gas, Se vapors, etc., for periods ranging from 1 minute to 30 minutes. If the precursor film comprises Se in addition to Cu, In and Ga, the annealing or the reaction step may be carried out in an inert atmosphere. In case Se vapor is used during reaction, the Se vapor may be generated by heating solid or liquid Se sources or by organometallic Se sources among others. To avoid segregation of Ga to the film/base interface, the Cu—In—Ga—Se reactions are not completed during this step. In other words, the precursor film is under-selenized leaving within the film binary and ternary phases such as Cu—Se, Ga—Se, In—Ga—Se, Cu—Ga, Cu—Ga—In, In—Ga, etc. This film obtained after Step II is a selenized film.

The third step (Step III) of the process involves a reaction step wherein the precursor film already reacted with Se, i.e. the selenized film, is further reacted with S species (i.e. sulfurized). Such reaction may be achieved in various ways. Typically, the reaction step may involve heating the precursor film to a temperature range of 200-600° C. in the presence of S provided by sources such as solid or liquid S, H₂S gas, S vapors, etc., for periods ranging from 1 minute to 60 minutes. The S vapor may be generated by heating solid or liquid S sources or by organometallic S sources, among others. During the reaction with S or sulfurization or sulfidation, the Ga species (such as Cu—Ga intermetallics, Ga—S species and Ga—In—S species, Cu—Ga—S species and Cu—In—Ga—S species) get distributed relatively uniformly (as shown in curve B of FIG. 2) through the layer. This is because reaction of Ga species with S is fast, unlike the reaction of Ga species with Se, which, as described before, is slow. As a result of the Step III (sulfurization) of the process a sulfurized film is formed on the base, the sulfurized film comprising Cu, In, Ga, Se and S, wherein the Ga is distributed substantially uniformly through the thickness of the film.

The last step (Step IV) of the process in FIG. 4 is substantial replacement of S in the sulfurized film with Se. This is the “final selenization” step. To achieve final selenization, the sulfurized film of Step III is exposed to Se species at elevated temperatures, preferably in the range of 250-600 C, more preferably in the range of 400-575 C, for a period of time which may be in the range of 1 minute to 1 hour, preferably in the range of 5 minutes to 30 minutes. As a result of the Step IV of the process, the Cu—In—Ga—S species of the sulfurized film is converted into a Cu(In,Ga)Se₂ absorber layer while the substantially uniform distribution of Ga within the film is preserved yielding a distribution similar to that shown in curve B of FIG. 2. It should be noted that by adjusting the times and temperatures employed during Step IV of the process, certain degree of S may be left in the absorber layer. The S/(Se+S) ratio in the final absorber layer may be less than 0.3, preferably less than 0.2, most preferably less than 0.1. Higher final selenization temperatures and/or longer final selenization times would replace more of the S within the sulfurized film with Se, thus yielding smaller S/(S+Se) ratio in the final absorber.

The processes described herein may be carried out in an in-line or roll-to-roll fashion, continuously, using the apparatus described in the following patent applications of the assignee of the present application: the application filed on Oct. 13, 2006 with Ser. No. 11/549,590 entitled Method and Apparatus for Converting Precursor Layers into Photovoltaic Absorbers, the application filed on Oct. 19, 2007 with Ser. No. 11/875,784 entitled Roll-to-Roll Electroplating for Photovoltaic Film Manufacturing, and the application filed on Nov. 12, 2007 with Ser. No. 11/938679 entitled Reel-to-Reel Reaction of Precursor Film to Form Solar Cell Absorber, which are incorporated herein by reference with their entire disclosures. In such an approach each portion of a base (such as a base in the form of a long web) travels from section to section of a reactor, getting exposed to pre-set temperatures and gas species in each section. For example, a portion of the base with a precursor film on it may first enter into a first section of a reactor where the reaction of the precursor film on that portion with S is carried out forming a sulfurized film. The portion then may travel to and enters a second section of the reactor where the sulfurized film may be reacted with Se species, i.e. selenized, at the second section of the reactor. By adding more sections to the reactor the process of FIG. 4 may also be carried out in a roll-to-roll or in-line manner.

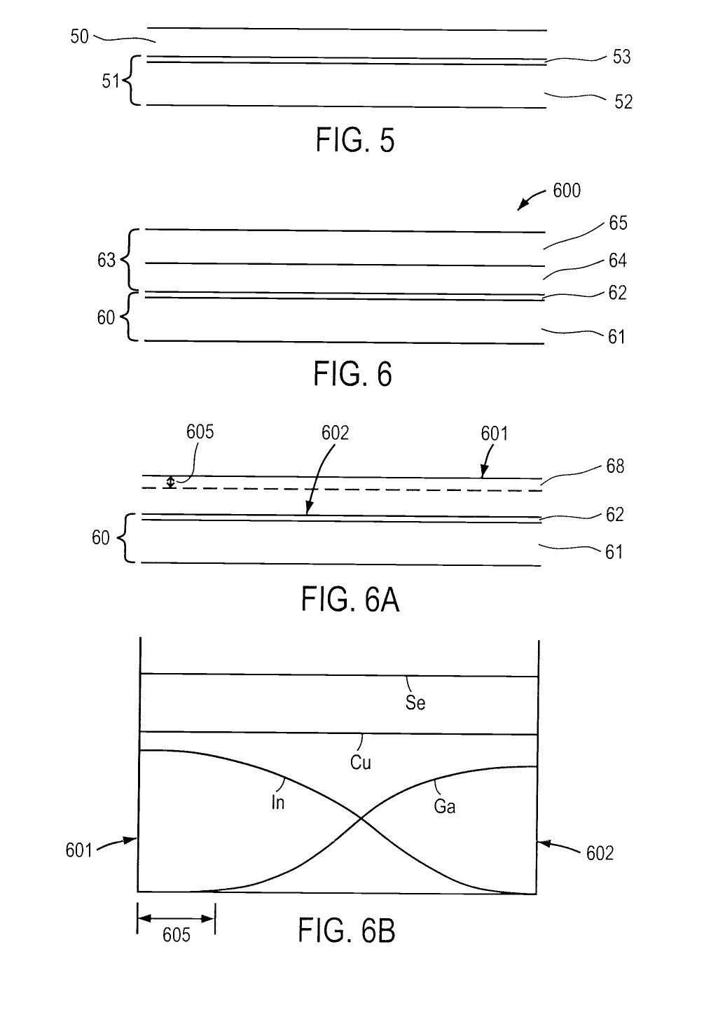

In another embodiment Te is used as a Ga-distribution agent for the Group IBIIIAVIA type absorber layers prepared by two stage processes. FIG. 5 shows a precursor layer 50 formed on a base comprising a substrate 52 and a contact layer 53. The precursor layer 50 may comprise Cu, In, Ga, Se and Te, wherein the Te/(Te+Se) molar ratio may be less than or equal to 0.3, preferably less than or equal to 0.2. Additionally the Te/Ga molar ratio may be less than or equal to 2, preferably less than or equal to 1, and more preferably less than or equal to 0.5. The preferable lower limits for the Te/Ga and Te/(Te+Se) molar ratios may be 0.1 and 0.005, respectively. It should be noted that the precursor layer 50 is not in the form of a Group IBIIIAVIA compound. In fact, a second stage of the process involving heat treatment and reaction is needed to convert the precursor layer 50 into the Group IBIIIAVIA compound. Typically, the reaction step may involve heating the precursor film to a temperature range of 400-600° C., optionally in the presence of Se provided by sources such as solid or liquid Se, H₂Se gas, organometallic Se vapor sources, elemental Se vapors, and the like, for periods ranging from 1 minute to 30 minutes. The heating rate from room temperature to the process or reaction temperature may be in the range of 1-50° C./seconds, preferably in the range of 5-20° C./seconds. In addition to Se or in place of Se, sulfur (S) may also be provided to the film during this reaction step. If the precursor film comprises excess amount of Se in addition to Cu, In and Ga, the annealing or the reaction step may be carried out in an inert atmosphere. In case Se vapor is used during reaction, the Se vapor may be generated by heating solid or liquid Se sources or by organometallic Se sources among others. In accordance with embodiments of the present inventions, it has been found that presence of a small amount of Te strategically located in the precursor layer assists the distribution of Ga throughout the Group IBIIIAVIA compound layer formed at the end of the reaction step. Specifically presence of Te close to the surface portion of the precursor layer 50, within the limits cited above, causes In and Ga to be distributed substantially uniformly through the thickness of the compound film formed after the reaction step. The embodiments will now be further described using specific examples.

### EXAMPLE 1

In the following example, a compound film formation without Te will be described. Accordingly, a first precursor film 63 is formed on a base 60 which includes a substrate 61 and a contact layer 62, as shown in FIG. 6. The first precursor film 63 may comprise a metallic layer 64 and a Se layer 65. The metallic layer 64 may be substantially made up of metallic ingredients such as Cu, In and Ga, and may include some impurities such as K, Na, Li and the like. The impurities may be present in an amount less than about 5 molar percent, preferably less than about 1 molar percent. As an example, the amount of Cu, In, and Ga in the metallic layer 64 may correspond to or may be equivalent to Cu, In and Ga thicknesses of about 150 nm, 206 nm, and 137 nm, respectively. Copper, In and Ga in the metallic layer 64 may be in the form of single or multi layers, mixtures, alloys, and the like. They may also be in the form of nano-particles, i.e. the metallic layer 64 may be a film formed using a nano-particle ink comprising Cu, In and Ga. Other methods of forming the metallic layer 64 include but are not limited to evaporation, sputtering and electrodeposition. A preferred method is electrodeposition of Cu, In and Ga, forming metallic layer 64 in the form of stacks such as Cu/In/Ga, Cu/In—Ga, Cu—In/Ga, Cu—Ga/In, Cu/Ga/In, Cu/Ga/Cu/In, Cu/Ga/In/Ga/Cu stacks and the like. Alternately, the metallic layer 64 may be an electrodeposited single layer of Cu—In—Ga. It should be noted that In—Ga, Cu—In, Cu—Ga and Cu—In—Ga refer to alloys or mixtures of “In and Ga”, “Cu and In”, “Cu and Ga”, and “Cu and In and Ga”, respectively.

It is straight forward to calculate the molar content of the metallic layer 64 from the equivalent thicknesses of its constituents. Accordingly, in the present example the 150 nm thick Cu, 206 nm thick In and 137 nm thick Ga provide approximately 2.1×10⁻⁶ moles of Cu, 1.31×10⁻⁶ moles of In, and 1.16×10⁻⁶ moles of Ga per centimeter square area of the metallic layer 64. Therefore, the Cu/(In+Ga) and the Ga/(Ga+In) molar ratios in the metallic layer 64 of this example are about 0.85 and 0.47, respectively.

The Se layer 65 in FIG. 6 is at least about 800 nm thick, which is the amount of Se needed to react with and convert all of the Cu, In and Ga in the metallic layer 64 into a Cu(In,Ga)Se₂ compound layer. It is, however, preferable to deposit 20-50% more Se on the metallic layer 64, because Se is a volatile material and, therefore, including an excess amount of Se in the precursor film 63 assures its availability during the subsequent high temperature reaction step. In the present example Se layer 65 has a thickness of about 1200 nm, providing about 7.28×10⁻⁶ moles of Se to the precursor film 63.

After formation of the first precursor film 63, the structure 600 is annealed at a temperature range of 500-600° C. for 5-20 minutes. In this example, annealing is carried out in a graphite box placed in a RTP system that heats the box at rates in the range of 5-20° C./second. The box also avoids excessive Se loss. After the reaction step, a first compound layer 68 is formed on the base 60 as shown in FIG. 6A. The first compound layer 68 has a top surface 601 and a bottom surface 602, which is in physical contact with the contact layer 62. FIG. 6B schematically shows a concentration depth profile (in arbitrary units) of the constituents of the first compound layer 68 of FIG. 6A. It should be noted that such depth profiles may be obtained using techniques such as Auger analysis, SIMS (secondary ion mass spectroscopy) analysis and microprobe analysis, all of which are well known in the field. The depth profile of FIG. 6B shows the distribution of Cu, In, Ga and Se through the first compound layer 68 starting from the top surface 601, going down to the bottom surface 602. As can be seen from this data, there is a segregation of Ga to near the bottom surface 602 and a segregation of In to near the top surface 601. This phenomenon results in the formation of a surface layer 605 in the first compound layer 68, the surface layer having a composition which is very close to that of CuInSe₂. In other words, the first compound layer 68 is a graded CIGS layer where the composition of the compound changes from CuInSe₂ near its surface to CuGaSe₂ or a highly Ga-rich phase near the contact layer. Such segregation is commonly observed in CIGS compound layers formed by the two-stage processes which involves reaction of a metallic layer comprising Cu, In and Ga with a Se layer or with Se vapor or with a Se-containing gas such as H₂Se.

A solar cell was fabricated using the first compound layer 68 by depositing a thin (˜100 nm) CdS buffer layer on the top surface 601 of the first compound layer 68 and by coating the CdS surface with a transparent conductive oxide (TCO). In this example ZnO was used as the TCO. The CdS buffer layer was deposited by chemical dip method and the TCO was deposited by sputtering. Finger patterns were then formed on the TCO layer to complete the device. Curve A in FIG. 8 shows the relative Quantum Efficiency (QE) data collected from this solar cell. As can be seen from this data, the long wavelength quantum efficiency extends to a wavelength range of about 1300 nm suggesting that the first compound layer 68 is not a CIGS layer with a uniform Ga/(Ga+In) molar ratio of 0.47. The bandgap value suggested by the data of Curve A is in the range of 0.95-1.0 eV, which is the bandgap for CuInSe₂. It should be noted that the bandgap value of a compositionally uniform CIGS layer with a Ga/(Ga+In) molar ratio of 0.47 would be in the range of approximately 1.3-1.4 eV, which is much larger than the value suggested by the QE data of Curve A. A bandgap value of 1.3-1.4 eV for an absorber layer of a solar cell would allow its QE to extend up to wavelengths in the range of 900-1100 nm, but not beyond. Therefore, the QE data of Curve A is in agreement with the depth profile of FIG. 6B confirming the presence of a low bandgap CuInSe₂ surface layer in the first compound layer 68.

### EXAMPLE 2

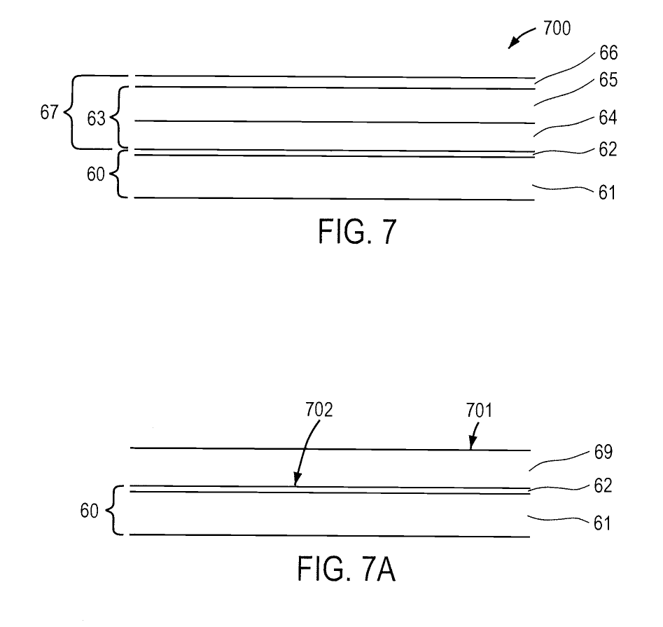

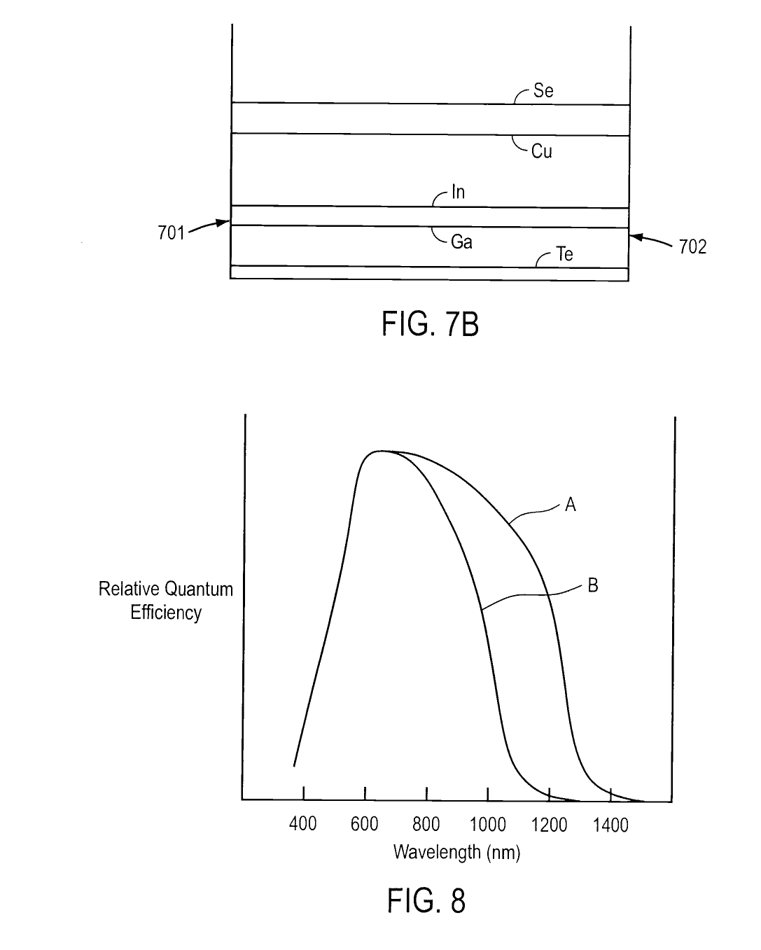

In the following example a compound film formation using Te as a Ga distribution agent will be described. Accordingly, a second precursor film 67 is formed on a base 60 which includes a substrate 61 and a contact layer 62, as shown in FIG. 7. The second precursor film 67 is formed by depositing a Te film 66 on the first precursor film 63 of FIG. 6. The Te film 66 may have a thickness in the range of 5-500 nm thick depending upon the equivalent thickness of the Ga in the second precursor film 67. The Te film preferably has a thickness in the range of 10-300 nm. In this example the thickness of the Te film 66 is about 80 nm. As explained in Example 1 above, it is straight forward to calculate the molar content of the metallic layer 64, the Se layer 65 and the Te film 66. Accordingly, in the present example the 150 nm thick Cu, 206 nm thick In, 137 nm thick Ga, 1200 nm thick Se and 80 nm thick Te provide approximately 2.1×10⁻⁶ moles of Cu, 1.31×10⁻⁶ moles of In, 1.16×10⁻⁶ moles of Ga, 7.28×10⁻⁶ moles of Se, and 0.4×10⁻⁶ moles of Te per centimeter square area of the second precursor film 67. Therefore, the Cu/(In+Ga) and the Ga/(Ga+In) molar ratios in the second precursor film 67 of this example are about 0.85 and 0.47, respectively. The Te/(Se+Te) molar ratio is about 0.05 in the second precursor film since there is excess Se included intentionally in this precursor. After the reaction, once the excess Se evaporates out, the Te/Se molar ratio in the compound layer would be about 0.08, instead of 0.05. The Te/Ga molar ratio, on the other hand is 0.34 and this ratio does not change much upon reaction.

After the formation of the second precursor film 67, the structure 700 is annealed at a temperature range of 500-600° C. for 5-20 minutes. In this example, annealing is carried out in a graphite box placed in a RTP system that heats the box at rates in the range of 5-20° C./second. The box also avoids excessive Se loss. After the reaction step, a second compound layer 69 is formed on the base 60 as shown in FIG. 7A. The second compound layer 69 has a top surface 701 and a bottom surface 702, which is in physical contact with the contact layer 62. FIG. 7B schematically shows a concentration depth profile (in arbitrary units) of the constituents of the second compound layer 69 of FIG. 7A. It should be noted that such depth profiles may be obtained using techniques such as Auger analysis, SIMS (secondary ion mass spectroscopy) analysis and microprobe analysis, all of which are well known in the field. The depth profile of FIG. 7B shows the distribution of Cu, In, Ga, Se and Te through the second compound layer 69 starting from the top surface 701, going down to the bottom surface 702. As can be seen from this data both In and Ga are distributed substantially uniformly through the thickness of the second compound layer 69. Specifically Ga is found to be present at and near the top surface 701. This result is very different from the result observed in FIG. 6B. Presence of only 80 nm thick Te in the overall precursor film influenced greatly the Ga and In distribution in the compound layer obtained after the reaction step.

A solar cell was fabricated using the second compound layer 69 by depositing a thin (˜100 nm) CdS buffer layer on the top surface 701 of the second compound layer 69 and coating the CdS surface with a TCO. The CdS buffer layer was deposited by chemical dip method and the TCO, which was a layer of ZnO, was deposited by sputtering. Finger patterns were then formed on the ZnO layer to complete the device. Curve B in FIG. 8 shows the QE data collected from this solar cell. As can be seen from this data, the long wavelength QE extends to a wavelength range of about 1100 nm suggesting that the second compound layer 69 has a substantially distributed Ga profile through its thickness. The bandgap value suggested by the data of Curve B is in the range of 1.25-1.3 eV, which is much larger than the bandgap for CuInSe₂. Therefore, the QE data of Curve B is in agreement with the depth profile of FIG. 7B confirming the influence of Te in distributing Ga and thus increasing the bandgap through the thickness of the second compound layer 69.

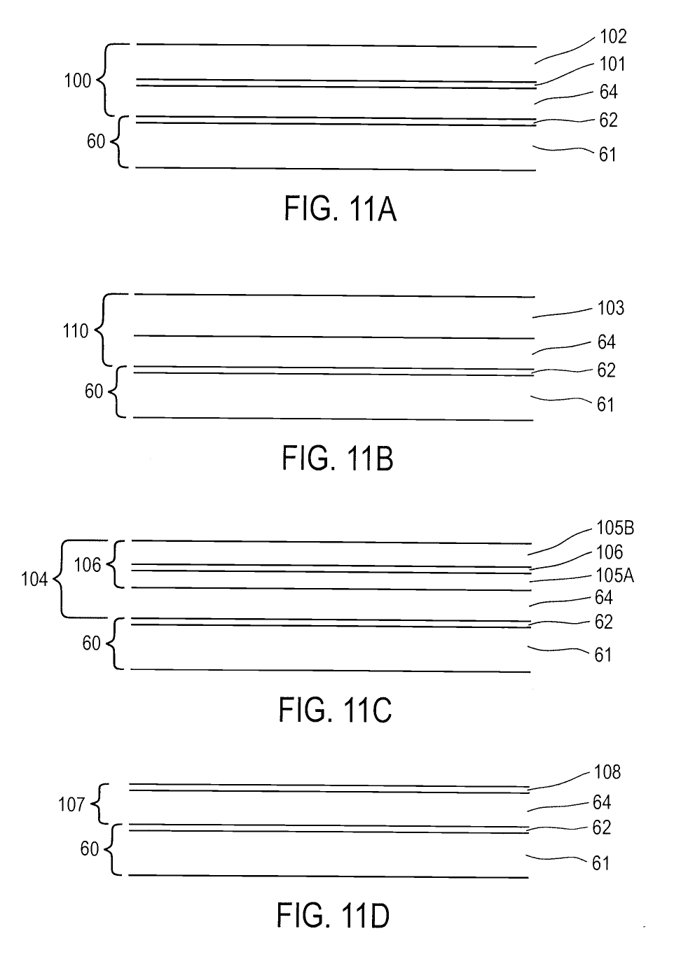

It should be noted that the Ga distribution achieved in Example 2 above may also be achieved by heating and reacting various other structures of precursor layers. Some of such exemplary precursor structures are shown in FIGS. 11A, 11B and 11C. In FIG. 11A a precursor layer 100 is formed by forming an interfacial Te layer 101 between the metallic layer 64 and a layer of Se 102. The nature of the metallic layer 64 was previously described with reference to FIGS. 6 and 7. FIG. 11B demonstrates another precursor layer 110 comprising the metallic layer 64 and a Group VIA material layer 103. In this case the Group VIA material layer 103 may comprise an alloy or mixture of Se and Te rather than discrete layers of Te and Se. FIG. 11C shows a multilayer precursor 104 comprising the metallic layer 64 and a layered Group VIA material structure 106. The layered Group VIA material structure 106 comprises a first Se layer 105A, a second Se layer 105B and a Te layer 106 between the first and second Se layers. It should be noted that the layered Group VIA material structure 106 may contain more layers of Se and/or Te.

As the examples above demonstrate, there is much flexibility for the placement of Te in the precursor structure as long as this placement keeps the Te away from the contact layer 62. Since the purpose of Te is to bring Ga from the bottom surface of the absorber to the top surface of the absorber or to keep Ga near the top surface of the absorber, Te needs to be present away from the bottom surface of the precursor layer, i.e. it should be kept away from the precursor layer/contact layer interface. Otherwise, Te would attract Ga to near the contact layer and yield results that are substantially opposite of what is desired. It should be noted that in a prior art method, a thin Te layer was deposited on the contact layer and a metallic precursor film comprising Cu and In was deposited on the Te layer. In this case Te was placed at the bottom surface precursor layer and its function was conditioning the surface of the contact layer so that nucleation of the precursor layer during its growth on the conditioned contact layer would be improved, yielding morphologically more uniform absorber films (see for example, Basol et al., Proceedings of 22^{nd} IEEE PV Specialists Conference, p. 1179, (1991), and Basol et al., Journal of Vacuum Science and Technology A, 14 (1996) 2251). It should be noted that controlling the Ga distribution through use of Te was not targeted in that work and the absorbers obtained had a high degree of segregated Ga near the contact layer, unless they were additionally annealed in absence of Se at high temperatures. High temperature annealing of CIGS layers in an inert atmosphere for extended periods of time is a known method that assists diffusion of Ga within the CIGS film (see for example, Marudachalam et al., Applied Physics Letters, 69 (1995) 3978).

Considering the above discussion and the fact that most Group IBIIIAVIA type absorber layers employed in solar cell structures have thicknesses in the range of 800-3000 nm, Te may be placed at least 200 nm, preferably at least 400 nm away from the back contact in the precursor structure. The precursor structure may have a total thickness in the range of 600-3000 nm. Placing Te away from the back contact assures that the influence of Te for distributing Ga and/or Al to the surface region of the absorber may be utilized properly.

Examples above used solid Se within the precursor structures. FIG. 11D shows yet another embodiment of a precursor coating 107 comprising a Te film 108 formed over the metallic layer 64. The precursor coating 107 may be converted into a CIGS type absorber layer by heat treating it at elevated temperatures in the presence of Se vapor species. This way, Se is provided by the reaction environment rather than by the precursor structure. It is, of course, also possible that Te may be distributed at the top 50-80% of the thickness of the metallic layer 64 (not shown) rather than deposited as the Te film 108 on the metallic layer 64.

Although the reasons behind the influence of Te on the Ga concentration profile in a Ga and In containing Group IBIIIAVIA compound layer are not fully understood, in the following, some of the plausible mechanisms will be discussed. It should be noted that possible mechanisms of the effect of Te may not be limited to those discussed here and the discussions here are not meant to be limiting.

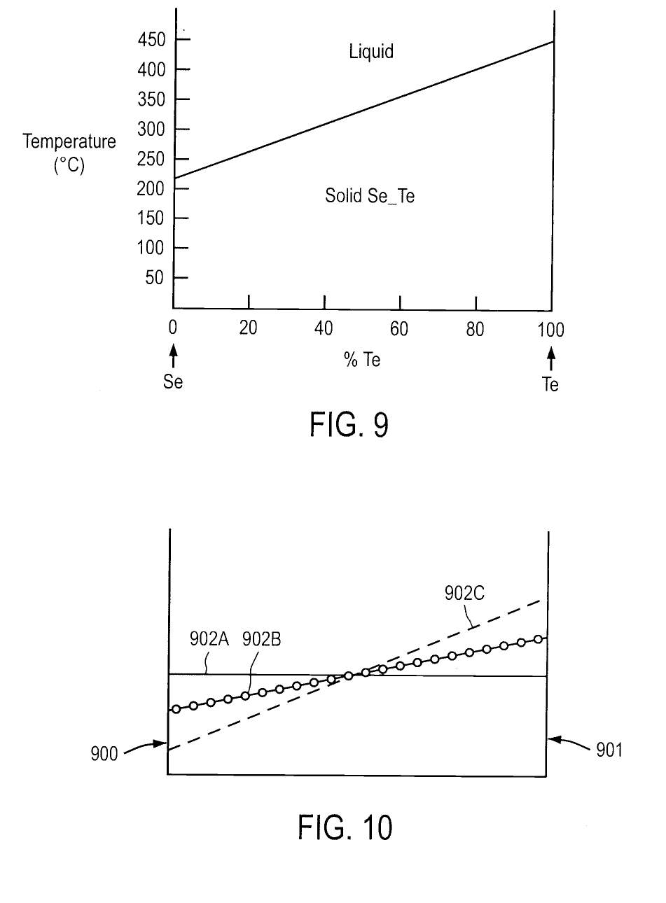

Tellurium (Te) has a higher melting point (449° C.) and boiling point (988° C.) than Se which has a melting point of 221° C. and a boiling point of 685° C. Higher boiling point of Te suggests that its vapor pressure is much lower than that of Se. Tellurium (Te) and Se are completely miscible, i.e. they form a continuous solid solution with all possible compositions between pure Se to pure Te. A schematic of Se—Te binary phase diagram is shown in FIG. 9. As can be seen from this diagram, the melting point of Se—Te alloy increases as the Te amount added to Se increases. Since the vapor pressure of Te is lower than that of Se, it is also possible that the vapor pressure of Se in a Se—Te melt is suppressed compared to its vapor pressure in pure Se melt. Both of these factors would influence the reaction process of Example 2. By adding Te to the second precursor film 67 a Se—Te melt may form as the temperature of the structure 700 (see FIG. 7) is raised beyond the melting point of Se during the reaction step. Due to its lower vapor pressure, the Se—Te melt may be less volatile and may provide Group VIA material to the metallic species more effectively compared to the volatile Se melt, much of which evaporate out of the precursor layer before having a chance to react. This may influence the reaction kinetics and allow Ga to react with the Group VIA species (Se, and Te) along with In rather than segregate to the back of the forming compound layer. It should be noted that use of Se—Te instead of pure Se in the precursor structure improves the utilization of Se by reducing its volatility. Increased melting point of Se—Te also improves morphology of the resulting compound layer. Wetting of the precursor layer surface by the Se—Te melt is better than the wetting by pure Se melt. This avoids formation of molten balls of Se on the precursor surface and thus improves the morphology of the resulting compound layer.

Another possible mechanism for the observed influence of Te may be that Ga may have a chemical affinity for reaction with Te species. As discussed before, it is known that In reacts first and at lower temperatures with Se compared Ga. This is thought to be one of the reasons for the observed segregation of In and Ga to the top and bottom surfaces of a compound layer, respectively, in two stage processes where the compound layer is formed by reacting metallic Cu, In and Ga with Se (see FIG. 6B and the discussion above). Reaction of Ga and Te species, however, may be more favorable than the reaction of In and Te species or at least there may not be a large difference between them. Therefore, In and Ga segregation which happens upon reaction with Se may be avoided by the presence of Te along with Se in the reaction environment. Another model explains the well known Ga and In segregation depicted in FIG. 6B by the fact that certain amount of Cu, In and Ga present in a precursor film may form intermetallic compounds such as Cu₁₁(In,Ga)₉ as the temperature of the precursor is raised during a reaction step. These compounds are stable and may stay metallic even in the presence of Se at temperatures as high as 350° C. and above. Excess In present in the precursor film, however, may easily react with Se near the surface of the precursor film at a temperature range of 220-300° C., forming an In-rich crust, which eventually turns into CuInSe₂ when Cu is released from the reaction of the intermetallic compounds with Se at high temperatures. It is, therefore, possible that presence of Te in the reaction environment changes this dynamics, possibly in a way that Te reaction with intermetallic compounds may take place at lower temperatures releasing Cu and Ga as well as In to the reaction through the whole thickness of the precursor layer.

Whatever the reason may be for the observed phenomenon, it is clear that addition of a small amount of Te to a precursor layer comprising Cu, In, Ga and Se causes Ga to be distributed through the thickness of the Group IBIIIAVIA compound layer formed after the reaction of all species. The Te is preferably placed away from the bottom surface of the precursor layer (bottom surface is defined as the surface in touch with the contact layer, whereas the top surface is the exposed surface of the precursor layer). The Te content may best be described in terms of molar ratios. Therefore, the Te amount in a precursor film may be such that the Te/Ga molar ratio within the precursor layer may be less than about 2, preferably less than 1 and most preferably less than 0.5. As can be seen from the Example 2 above, a Te/Ga ratio of 0.34 was highly effective in distributing Ga. Other experiments with Te/Ga ratio of 0.2 and 0.1 were also found to bring Ga to the surface of the compound layer after reaction. A Te/Ga ratio of 1 would mean that reaction of all the Ga in the precursor layer may be dominated by an equal molar content of Te. A Te/Ga ratio of 2, on the other hand, lets some Te to be available for reactions with In also. It should be noted that as the Te/Ga ratio increases beyond 1 the electronic quality of the Cu(In,Ga)(Se,Te)₂ would be affected more and more by telluride, which is not as good a solar cell material as CIGS. Therefore, the preferred Te/Ga molar ratio is less than 1 and most preferably it is less than 0.5. To be effective, the Te/Ga molar ratio may be more than about 0.05. Another way of expressing the Te content of the compound layer is the Te/(Se+Te) molar ratio. This ratio may be less than or equal to 0.3, preferably less than or equal to 0.2.

It may be possible to control the nature of the Ga and In profiles in a Group IBIIIAVIA compound material film obtained by the two-stage process by controlling the Te amount in the precursor layer employed in the process. For example, FIG. 10 shows three different Ga profiles. The first Ga profile 902A is substantially uniform through the film from its top surface 900 to its back surface 901. The second Ga profile 902B represents a situation where the Ga concentration increases gradually from the top surface 900 towards the back surface. The third Ga profile 902C is highly graded but still the Ga content near and at the top surface 901 is higher compared to the case shown in FIG. 6B. The Ga profiles 902A, 902B and 902C may be obtained by varying the Te/Ga molar ratio in the precursor used to form the Group IBIIIAVIA compound layer. As the Te/Ga molar ratio is increased from zero (case shown in FIGS. 6A and 6B) to, for example, 0.5, the Ga profiles 902C, 902B and eventually 902A may be obtained after the reaction step that forms the compound layer. It should be noted that the embodiments have been described using CIGS as the example. However, Ag, which is also a Group IB material may be partially or wholly substituted for Cu. Aluminum (Al) may be wholly or partially substituted for Ga. Just like Ga, Al also segregates to the back surface of the compound film when Cu(In,Al)Se₂ compound film is formed by reacting a metallic precursor comprising Cu, In and Al with Se. Therefore, the arguments made for CIGS are also valid for CIAS (copper indium aluminum selenide) or for compounds comprising both Ga and Al. It should also be noted that some S may also be added to the composition of the compound films.

In the embodiment described with respect to FIG. 7, Te is added to the precursor layer in the form of a cap deposited over the Se layer. It is possible to introduce Te in various other ways. Tellurium (Te) may, for example, be deposited in the form of a layer on a metallic film comprising Cu, In and Ga. Selenium (Se) may then be deposited on the layer of Te (FIG. 11A). Alternately, Te may be sandwiched between two layers of Se (FIG. 11C). Tellurium (Te) and Se may also be deposited in the form of a mixture or alloy (FIG. 11B) instead of separate distinct layers.

Although the aspects and advantages and of present inventions are described with respect to certain preferred embodiments, modifications thereto will be apparent to those skilled in the art.

What is claimed is:

1. A method of forming a Group IBIIIAVIA compound layer on a base comprising:
forming a precursor on the base, the precursor comprising at least one Group IB material, indium (In), tellurium (Te) and at least one of gallium (Ga) and aluminum (Al), wherein the step of forming the precursor comprises growing a first layer on the base, the first layer comprising at least one of the indium (In), gallium (Ga), aluminum (Al) and a Group IB material and excluding tellurium (Te), and depositing a second layer comprising tellurium (Te) on the first layer;
reacting the precursor with selenium (Se); and
forming the Group IBIIIAVIA compound layer on the base.

2. The method of claim 1 wherein the step of growing the first layer grows the first layer to a thickness of at least 200 nm.

3. The method of claim 1, wherein the precursor comprises copper (Cu), indium (In), tellurium (Te) and gallium (Ga) and wherein the step of forming the precursor comprises growing the first layer on the base, the first layer comprising at least one of copper (Cu), indium (In) and gallium (Ga) and excluding tellurium (Te), and depositing a second layer comprising tellurium (Te) over the first layer.

4. The method of claim 3 wherein the step of growing the first layer grows the first layer to a thickness of at least 200 nm.

5. The method of claim 4 wherein a molar ratio of tellurium (Te) to gallium (Ga) in the precursor is less than or equal to 1.

6. The method of claim 5, wherein the step of reacting is carried out at a temperature range of 400-600°C.

7. The method of claim 6, wherein the step of reacting the precursor with selenium (Se) is carried out in an atmosphere comprising gaseous selenium (Se) species.

8. The method of claim 6, wherein at least one of the steps of growing the first layer and depositing the second layer also introduces selenium (Se) into the precursor.

9. The method of claim 7, wherein at least one of the steps of growing the first layer and depositing the second layer also introduces selenium (Se) into the precursor.

10. The method of claim 8, wherein the Te/Ga molar ratio is between 0.05 and 0.5.

11. A method of forming a Group IBIIIAVIA compound layer on a base comprising:
forming a precursor on the base by way of depositing a precursor material by initiating the deposition at a beginning deposition stage and ending the deposition at a final deposition stage, wherein the precursor material comprises at least one Group IB material, indium (In) as a Group IIIA material, at least one other Group IIIA material and tellurium (Te), and wherein the tellurium (Te) is deposited during at least one of the final deposition stage and an intermediate deposition stage that takes place between the beginning deposition stage and the final deposition stage;
providing selenium (Se);
reacting the precursor with selenium (Se); and
forming the Group IBIIIAVIA compound layer on the base.

12. The method of claim 11, wherein a molar ratio of tellurium (Te) to the at least one other Group IIIA material is less than or equal to 1.

13. The method of claim 12, wherein the Group IB material is at least one of copper (Cu) and silver (Ag) and the at least one other Group IIIA material is at least one of gallium (Ga) and aluminum (Al).

14. The method of claim 13, wherein the Group IB material is Cu, the at least one other Group IIIA material is Ga, and wherein the Te/Ga molar ratio in the precursor is less than 1.

15. The method of claim 14, wherein the step of reacting is carried out at a temperature range of 400-600°C.

16. A method of forming on a surface of a base, a Cu(In,Ga)(Se,Te)₂ compound layer with a top surface and a bottom surface, wherein the bottom surface is adjacent to the surface of the base and wherein indium (In) and gallium (Ga) are distributed substantially uniformly between the top surface and the bottom surface, the method comprising;
depositing a metallic layer on the surface of the base, wherein the metallic layer comprises copper (Cu), In and Ga, and wherein the thickness of the metallic layer is at least 200 nm;
disposing a film comprising selenium (Se) and tellurium (Te) over the metallic layer thus forming a structure; and
heating the structure to a temperature range of 400-600° C.

17. The method of claim 16, wherein the molar ratio of Te to Ga is less than or equal to 1.

18. The method of claim 17, wherein the step of heating is carried out in presence of gaseous Se species.

19. The method of claim 17, wherein the film comprises one of a Te/Se stack and Se/Te stack.

20. The method of claim 17, wherein the film comprises one of a Se—Te mixture and Se—Te alloy.

21. The method of claim 17, wherein the metallic layer comprises a stack of at least one Cu film, one In film and one Ga film.

22. The method of claim 21, wherein the metallic layer is electrodeposited over the base.

23. The method of claim 22, wherein the film is electrodeposited over the metallic layer.

24. The method of claim 17, wherein the Te/Ga molar ratio is between 0.05 and 0.5.

25. The method of claim 19, wherein the Te/Ga molar ratio is between 0.05 and 0.5.

26. The method of claim 20, wherein the Te/Ga molar ratio is between 0.05 and 0.5.

27. A precursor structure for forming a Group IBIIIAVIA solar cell absorber on a surface of a base, comprising:
a metallic layer formed on the surface of the base, the metallic layer comprising at least one Group IB material, indium (In) as a Group IIIA material and at least one another Group IIIA material, wherein the thickness of the metallic layer is at least 200 nm; and
a Group VIA layer comprising tellurium (Te) and selenium (Se) formed on the metallic layer.

28. The structure of claim 27, wherein the molar ratio of tellurium (Te) to the at least one another Group IIIA material is less than or equal to 1.

29. The structure of claim 28, wherein the at least one Group IB material comprises one of copper (Cu) and silver, and the at least one another Group IIIA material comprises one of gallium (Ga) and aluminum (Al).

30. The structure of claim 29, wherein the at least one Group IB material is copper (Cu) and the at least one another Group IIIA material is gallium (Ga), and wherein the molar ratio of tellurium (Te) to gallium (Ga) is less than 1.

31. The structure of claim 28, wherein the Group VIA layer comprises one of a selenium (Se)/tellurium (Te) stack and a tellurium (Te)/selenium (Se) stack.

32. The structure of claim 28, wherein the Group VIA layer comprises one of a selenium (Se)-tellurium mixture and a selenium (Se)-tellurium (Te) alloy.

33. The structure of claim 30, wherein the metallic layer comprises a stack of at least one copper (Cu) film, one indium (In) film and one gallium (Ga) film.

34. The structure of claim 28, wherein the tellurium (Te) to gallium (Ga) molar ratio is between 0.05 and 0.5.

35. The structure of claim 31, wherein the tellurium (Te) to gallium (Ga) molar ratio is between 0.05 and 0.5.

36. The structure of claim 32, wherein the tellurium (Te) to gallium (Ga) molar ratio is between 0.05 and 0.5.

37. A solar cell absorber layer, having a top surface and a bottom surface, formed on a base, wherein the bottom surface is adjacent to the base, comprising:
copper (Cu), gallium (Ga), indium (In), selenium (Se), and tellurium (Te); and
wherein indium (In) and gallium (Ga) are distributed substantially uniformly between the top surface and the bottom surface of the solar cell absorber layer, and the molar ratio of Te to Ga is less than 1.

38. The solar cell absorber layer of claim 37, wherein the tellurium (Te) to gallium (Ga) molar ratio is between 0.05 and 0.5.

39. The solar cell absorber layer of claim 37, wherein the molar ratio of tellurium (Te) to both selenium (Se) and tellurium (Te) is less than 0.2.
